(19) United States
(12) Patent Application Publication
(10) Pub. No.: US 2018/0323105 A1
(43) Pub. Date: Nov. 8, 2018

(54) Simultaneous Break and Expansion System for Integrated Circuit Wafers

(71) Applicant: pSemi Corporation, San Diego, CA (US)

(72) Inventors: Vincent DeMaioribus, Carlsbad, CA (US); John James, Poway, CA (US)

(21) Appl. No.: 15/957,794

(22) Filed: Apr. 19, 2018

Related U.S. Application Data
(60) Provisional application No. 62/500,420, filed on May 2, 2017.

(51) Int. Cl. H01L 21/78; H01L 21/683; B26F 3/00; B28D 1/22

(52) U.S. Cl. CPC H01L 21/78; B28D 1/225; B26F 3/002; H01L 21/6836

(57) ABSTRACT

Improved methods and apparatuses for singulating integrated circuit (IC) dies that reduce or eliminate die collisions and work well with very small dies. Embodiments simultaneously separate dies in two dimensions by utilizing a break and expansion system that avoids die collisions by maintaining IC die separation after singulation. Singulation is achieved by placing the joined dies of the wafer substrate on a dicing tape, scoring the wafer substrate between the joined dies, and imposing a bending action by pressing a curved surface against the scored wafer substrate, which also expands the wafer substrate by stretching the dicing tape. After breaking, an inner expansion grip ring is pressed into an outer expansion grip ring in a nested configuration so as to maintain the stretched state of the dicing tape after the curved surface is fully removed, thereby maintaining the dicing tape in tension and the singulated die in spaced apart relation.

### CROSS-REFERENCE TO RELATED APPLICATIONS—CLAIM OF PRIORITY

The present application claims priority to U.S. provisional Patent Application No. 62/500,420, filed on May 2, 2017, for a “Simultaneous Break and Expansion System for Integrated Circuit Wafers”, which is herein incorporated by reference in its entirety. This application may be related to U.S. patent application Ser. No. 15/432,838, filed Feb. 14, 2017, entitled “Wafer Dicing Methods”, assigned to the assignee of the present invention and hereby incorporated by reference.

### BACKGROUND

### (1) Technical Field

This invention relates to methods for the singulation of integrated circuit dies from processed wafer substrates, also known as “wafer dicing”.

### (2) Background

Integrated circuits (ICs) are almost universally fabricated as multiple units formed on round wafer substrates. Common wafer substrates include silicon, sapphire, silicon-on-insulator (SOI), silicon-on-sapphire (SOS), gallium arsenide, and various insulators (e.g., ceramics, glasses, crystalline quartz, piezoelectrics, etc.), but a wide variety of other materials have been used. In general, multiple individual IC die, typically numbering in the hundreds to thousands, are formed as complex two-dimensional and three-dimensional patterns of insulating, semiconductive, and conductive materials on one side of a wafer substrate. IC functionality may include electronic, micromechanical, sensor, and/or other technologies.

Individual dies are generally separated from other dies on a wafer substrate by cutting “streets” (also known as dicing “lanes” or “kerfs”). Die singulation, also known as wafer dicing, is part of the fabrication process that separates individual dies on a wafer substrate for further packaging or direct usage. Wafer dicing is one of the most critical elements of the IC fabrication process, where reduction of defects and improvements in quality can make a significant contribution to final yield and lower per unit costs for the ICs. Defects may include chipped IC die edges and stress fractures that reduce IC die strength and increase the chance of breaking during later assembly steps or in actual use. Due to the crystalline nature of most wafer substrates, die chipping may occur simply when singulated dies rub or strike each other (also known as “die collisions”).

A number of mechanical-based and non-mechanical methods have been developed for singulating dies from a wafer substrate along cutting streets. Mechanical-based methods include, for example, diamond scribing to create cleave lines, and rotary blade saws to create partial-depth cleave lines or full-depth cuts through a wafer substrate. Non-mechanical methods include, for example, ablative lasers that essentially sublime and/or vaporize material along cutting streets, plasma etching that uses hot ions to essentially vaporize and “sand blast” such material, and so-called “stealth” dicing based on use of infrared (IR) lasers to create subsurface sites suitable to form preferred cleaving planes.

With respect to stealth dicing, a number of thin wafer substrate materials, such as silicon, are substantially transparent to infrared light. Stealth dicing IR lasers generally penetrate the backside surface of such wafer substrates—or the front side, if the cutting streets are clear. Focused heating from the laser creates highly localized and brief melting, transforming crystalline material (e.g., silicon) into a modified material (e.g., polycrystalline silicon) surrounded by a field of concentrated stress and micro cracks. The IR laser is often sequentially focused at different depths in a wafer substrate, so that stacked vertical planes of modified material are formed. These subsurface modified layers essentially create weakened cleaving planes that enable mechanical separation. Stealth dicing generally leaves no visible marks on the outer surface of a wafer substrate.

The chosen method of wafer dicing generally depends on such factors as wafer substrate material and thickness, presence of complicating materials (e.g., metal, test element groups (TEGs), etc.) within the cutting streets (“in-street structures”), metallization on the backside of a wafer substrate, defect type and degree, and kerf width produced by the singulating method (wide kerfs reduce the number of available dies from a wafer substrate). For example, the presence of metal and/or TEGs within cutting streets generally prohibits use of cutting saws, since such in-street structures may clog a saw. Rotary blade cutting and mechanical scribing can also cause die edge chipping or cracking, leading to lower yields, and both methods generally have relatively wide kerfs (e.g., greater than about 50 μm). Backside metallization may prohibit use of certain laser-based methods, or pose cutter alignment problems. Stealth dicing generally does not work for IC dies having in-street metal or TEGs on the patterned front side of a wafer substrate, since the subsurface modified layers do not cut the front-side structures, resulting in errant breaks in the metal and/or inability to separate dies.

If a selected dicing method does not completely separate individual dies from a wafer substrate (such as by sawing all of the way through the wafer substrate), the wafer substrate requires an additional step to actually separate the individual dies. The action of singulation methods that generate a partial-depth cut, a scribe, a cleaving plane, a stealth dicing cleaving plane, or the like along cutting streets of a wafer substrate but do not completely separate individual dies from a wafer will be referred to in this document as “scoring” the wafer substrate, with the result being a “scored” wafer.

For example, FIG. 1 is a side-view of a stylized prior art singulation process 100 using tape expansion. In this method, a wafer 102 is affixed to a dicing tape 104 gripped on its perimeter by a frame 106; the wafer 102 is then scored. As is known, dicing tape is a backing tape used to hold IC dies together during and after the wafer dicing process; the IC dies are removed from the dicing tape later in the manufacturing process. Thereafter, a flat plate 108 is pressed against the dicing tape 104 to expand (stretch) the dicing tape 104, which causes the individual dies of the scored wafer 102 to pull away from each other due to lateral tension (in FIG. 1, the individual dies 110 are shown post-expansion).

A problem with the method of FIG. 1 is that it does not work well with very small dies (e.g., less than about 1.0 mm on the shortest edge). In addition, when the expansion tension is released, if the dicing tape has not yielded under expansion, the dicing tape memory will pull the dies back together, which may cause damaging die collisions. Alternatively, when the expansion tension is released, if the dicing tape has yielded, the dicing tape becomes slack, which again may cause damaging die collisions. In a variant of the process depicted in FIG. 1, the singulation process may be conducted in a cooling chamber, which aids in singulating smaller die, but still suffers the problem of allowing post-expansion die collisions.

As another example, FIG. 2 is a side-view of a stylized prior art singulation process 200 using a moving breaker bar or roller. In this method, a wafer 202 is again affixed to a dicing tape 204 gripped on its perimeter by a frame 206, and the wafer 202 is then scored. A tensioning mechanism 208 imposes some lateral tension on the scored wafer 202, but die separation is caused by the movement of a breaking bar 209 across one dimension of the scored wafer 202. Local deformation of the scored wafer 202 under the applied force of the breaking bar 209 causes the individual dies 210 to break away from the scored wafer 202 along edges perpendicular to the movement of the breaking bar 209, leaving “columns” of connected dies after a first pass; FIG. 2 also shows joined (non-singulated) dies 211 of the scored wafer 202 that have not yet been mechanically separated by the breaking bar 209. After passing from one side to the other, the scored wafer 202 is rotated 90° and a second pass is made by the breaking bar 209 to break the columns of connected dies into individual dies 210.

A problem with the method of FIG. 2 is that a frame 206 much larger than the scored wafer 202 is required to accommodate the breaking bar 209 (not shown to scale in FIG. 2). For example, if the scored wafer 202 has a 300 mm diameter, then a frame 206 that can accommodate a 450 mm diameter wafer substrate is required to allow the breaking bar 209 (which must be at least 300 mm long to span the entire diameter of a 300 mm wafer substrate) to fit within the opening of the frame 206 supporting the scored wafer 202 on the dicing tape 204. It is expensive to utilize die singulation equipment that can handle such different sized components. Alternatively, a customized and expensive breaking bar machine must be designed to accommodate existing frames used with a particular wafer size. Further, it is believed that some portion of the dies will at least partially separate from the dicing tape during expansion, which adversely affects later processing steps, and die movement as the breaking bar 209 traverses the scored wafer 202 is likely to lead to damaging die collisions. In addition, the breaking bar 209 must be fairly precisely aligned with the orientation of the scorings of the scored wafer 202, in both pass directions. Moreover, the method of FIG. 2 suffers the same post-expansion die collision problems as the method of FIG. 1.

As a further example, FIG. 3 is a side-view of a stylized prior art singulation process 300 using a cutting blade and anvil. In this method, a wafer 302 is again affixed to a dicing tape 304 gripped on its perimeter by a frame 306, and the wafer 302 is then scored. Die singulation is caused by reciprocating movement of a front-side cutter blade 307a against a back-side anvil 307b to physically separate individual dies 310 from the scored wafer 302 along edges perpendicular to the lateral movement of the cutter blade 307a, leaving “columns” of connected dies after a first pass; FIG. 3 also shows joined dies 311 of the scored wafer 302 that have not yet been mechanically cut by the cutter blade 307a. After passing from one side to the other, the scored wafer 302 is rotated 90° and a second pass is made by the cutter blade 307a to break the columns of connected dies into individual dies 310. The dicing tap is generally expanded following cutting.

The method of FIG. 3 has problems similar to the method of FIG. 2. In addition, the cutter blade 307a and/or anvil 307b may damage structures on the front or back sides of the individual dies 210, such as solder bumps. Further, as cutting and expansion are done on separate machines or stations, the handling of the fully singulated wafer substrate between processes may cause damaging die collisions.

The problems of the prior art methods of singulating dies can increase with certain types of wafer substrates. For example, most production wafer substrates are dedicated to same-size rectangular IC dies arrayed in a two-dimensional grid. Accordingly, most or all of such IC dies having a shortest edge dimension above a minimum size (e.g., exceeding about 1 mm) can be separated by one of the methods described above. However, some wafer substrates, referred to as multi-project wafers or multi-product wafers (MPWs), contain different size IC dies and/or non-uniform grid pattern layouts of ICs and/or non-rectangular ICs. As described in co-pending U.S. patent application Ser. No. 15/432,838, referenced above, developing efficient cutting plans for MPWs is problematic, owing to the non-regular layouts of ICs on such wafer substrates.

Accordingly, there is a need for an improved method for singulating integrated circuit dies that reduces or eliminates die collisions, works well with very small dies (e.g., less than about 1.0 mm on the shortest edge), and works well with both uniform grid patterns die layouts and non-uniform grid pattern die layouts (e.g., MPWs). It would be highly beneficial if such a die singulating method could simultaneously separate dies in two dimensions. The present invention addresses these and other needs.

### SUMMARY OF THE INVENTION

The invention encompasses improved methods for singulating integrated circuit (IC) dies that reduce or eliminate die collisions, work well with very small dies (e.g., less than about 1.0 mm on the shortest edge), and work well with both uniform grid patterns die layouts and non-uniform grid pattern die layouts (e.g., multi-project wafers or multi-product wafers). Further, embodiments of the invention simultaneously separate dies in two dimensions.

Embodiments of the invention utilize a simultaneous break and expansion system for separating individual IC dies from a scored wafer substrate, and avoid die collisions by maintaining IC die separation once singulation has occurred. The system may use a variety of scored wafer substrates, and works well in particular with wafer substrates that have been both laser scribed and stealth diced.

More specifically, a wafer substrate is affixed to a dicing tape and the dicing tape is in turn affixed to a frame (directly or by means of a tension maintenance device); the wafer substrate is then scored. Singulation by breaking is achieved by placing the joined dies of the scored wafer substrate in tension by a bending action. The bending action is imposed by pressing a 2-dimensionally curved surface (e.g., a spherical surface) against the scored wafer substrate through the dicing tape. When forced against the scored wafer substrate, the curved surface simultaneously expands the scored wafer substrate in both length and width directions by stretching the dicing tape, and induces bending torque in both directions. Accordingly, at this point, the individual dies of the scored wafer substrate are: cleaved along the cleave planes; physically separated from each other; and spaced apart from each other, essentially eliminating die collisions.

After breaking the scored wafer substrate and stretching the dicing tape by pressing the curved surface against the scored wafer substrate (through the dicing tape), a tension maintenance device is applied; for example, an inner expansion grip ring may be pressed into contact with the dicing tape and into an outer expansion grip ring in a nested configuration so as to maintain the stretched state of the dicing tape before the tension imposed by the curved surface is fully removed. Such outer and inner expansion grip rings work on the same principle as embroidery rings, and accordingly maintain the dicing tape in tension after the curved surface is retracted from contact with the dicing tape and scored wafer substrate. The tensioned dicing tape thus keeps the individual separated dies spaced apart from each other, essentially eliminating die collisions.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1 is a side-view of a stylized prior art singulation process using tape expansion.

FIG. 2 is a side-view of a stylized prior art singulation process using a moving breaker bar or roller.

FIG. 3 is a side-view of a stylized prior art singulation process using a cutting blade and anvil.

FIG. 4 is a stylized diagram of a simultaneous break and expansion system in accordance with the present invention.

FIG. 5A is a side view of a stylized embodiment of a simultaneous break and expansion system, showing a pre-contact state for a curved surface.

FIG. 5B is a side view of the stylized embodiment of the simultaneous break and expansion system of FIG. 5A, showing an initial contact state for the curved surface.

FIG. 5C is a side view of the stylized embodiment of the simultaneous break and expansion system of FIG. 5A, showing a full contact state for the curved surface.

FIG. 5D is an enlarged view of two adjacent and joined dies of the pre-expansion scored wafer substrate of FIG. 5B.

FIG. 5E is an enlarged view of two adjacent separated dies of the post-separation scored wafer substrate of FIG. 5C.

FIG. 5F is a side view of the stylized embodiment of the simultaneous break and expansion system of FIG. 5C, showing commencement of post-separation tensioning.

FIG. 5G is a side view of the stylized embodiment of the simultaneous break and expansion system of FIG. 5F, showing completion of post-separation tensioning.

FIG. 6A is a top plan view of a scored MPW substrate mounted on a dicing tape affixed to a frame (not shown) and stretched or affixed to across an outer expansion grip ring.

FIG. 6B is a top plan view of the post-separation state for FIG. 6A, showing the separation of the dies maintained by the inner and outer expansion grip rings.

FIG. 7A is a top plan view of a scored wafer substrate mounted on a dicing tape affixed to a frame (not shown) and stretched across or affixed to an outer expansion grip ring.

FIG. 7B is a top plan view of the post-separation state for FIG. 7A, showing the separation of the dies maintained by the inner and outer expansion grip rings.

FIG. 8 is a process flow diagram showing a first method for singulating joined IC dies from a wafer substrate.

FIG. 9 is a process flow diagram showing a second method for singulating joined IC dies from a wafer substrate.

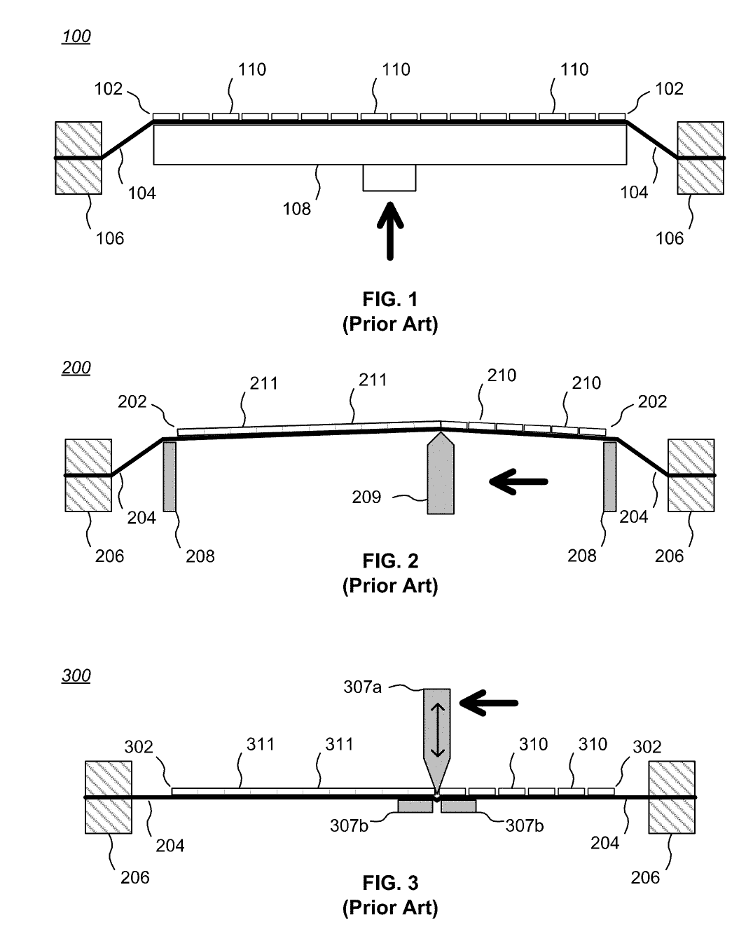

Like reference numbers and designations in the various drawings indicate like elements.

### DETAILED DESCRIPTION OF THE INVENTION

The invention encompasses improved apparatus and methods for singulating integrated circuit (IC) dies that reduce or eliminate die collisions, work well with very small dies (e.g., less than about 1.0 mm on the shortest edge), and work well with both uniform grid patterns die layouts and non-uniform grid pattern die layouts (e.g., multi-project wafers or multi-product wafers). Further, embodiments of the invention simultaneously separate dies in two dimensions.

Embodiments of the invention utilize a simultaneous break and expansion system for separating individual IC dies from a scored wafer substrate, and avoid die collisions by maintaining IC die separation once singulation has occurred. The system may use a variety of scored wafer substrates, and works well in particular with wafer substrates that have been both laser scribed and stealth diced in accordance with the teachings of co-pending U.S. patent application Ser. No. 15/432,838, referenced above.

Overview of Concept

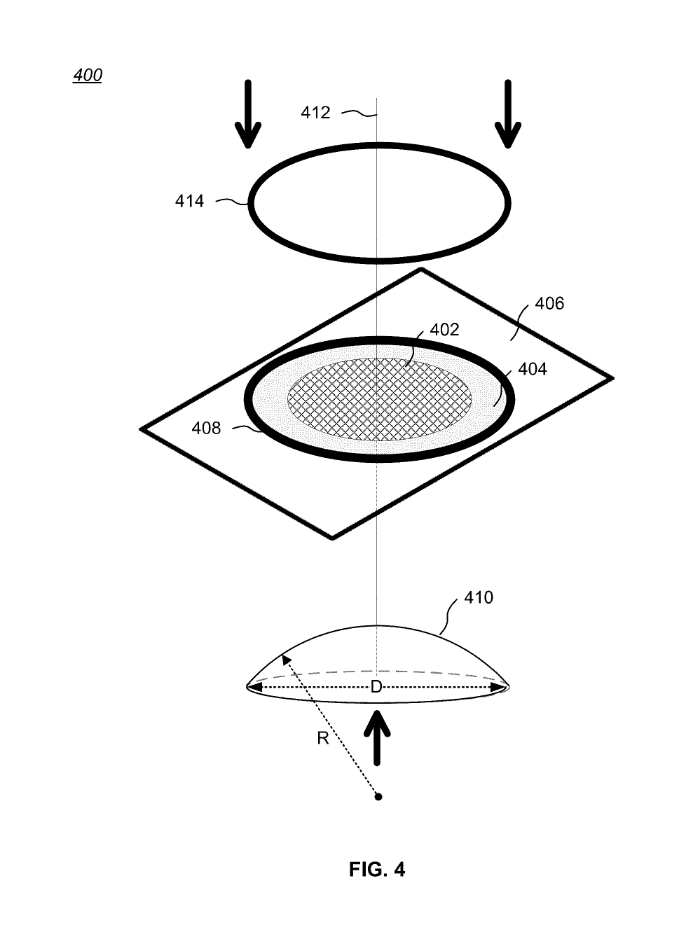

FIG. 4 is a stylized diagram of a simultaneous break and expansion system 400 in accordance with the present invention. A wafer substrate 402 is affixed to a dicing tape 404 in conventional fashion, and the dicing tape 404 is in turn affixed to a conventional frame 406 (directly or by means of a tension maintenance device, such as an outer expansion grip ring 408); the order of affixation may be reversed in some applications if desired. The frame 406 facilitates manual and mechanized handling to avoid damage to the wafer substrate 402. The wafer substrate 402 is then scored.

Singulation by breaking is achieved by simultaneously placing the joined dies of the scored wafer substrate 402 in tension and applying a breaking torque at the scoring lines by a bending action. The bending action is imposed by pressing a 2-dimensionally curved surface 410 (e.g., an approximately spherical surface) against the scored wafer substrate 402 (through the dicing tape 404 in this example), preferably near the center line 412 of the scored wafer substrate 402 (note that the curvature of the curved surface 410 is exaggerated for purposes of illustration). When forced against the scored wafer substrate 402, the curved surface 410 simultaneously breaks the dies from each other by applying a bending force to all of the scoring lines and expands the scored wafer substrate 402 by stretching the dicing tape 404. Accordingly, at this point, the individual dies of the scored wafer substrate 402 are physically separated from each other and spaced apart from each other, essentially eliminating die collisions.

After breaking the scored wafer substrate 402 and stretching the dicing tape 404 by pressing the curved surface 410 against the scored wafer substrate 402 (through the dicing tape 404 in this example), a tension maintenance device is applied. For example, an inner expansion grip ring 414 may be pressed into the outer expansion grip ring 408 in a nested configuration so as to maintain the stretched state of the dicing tape 404 before the tension imposed by the curved surface 410 is fully removed. Such outer and inner expansion grip rings 408, 414 work on the same principle as embroidery rings, and accordingly maintain the dicing tape 404 in tension after the curved surface 410 is retracted from contact with the dicing tape 404 and scored wafer substrate 402. The tensioned dicing tape 404 thus keeps the individual dies spaced apart from each other, essentially eliminating die collisions. As should be apparent, the individual dies are never placed in compression during expansion and separation, and the dicing tape 404 is never in a slack state post-expansion; accordingly die collisions cannot occur.

### Detailed Example

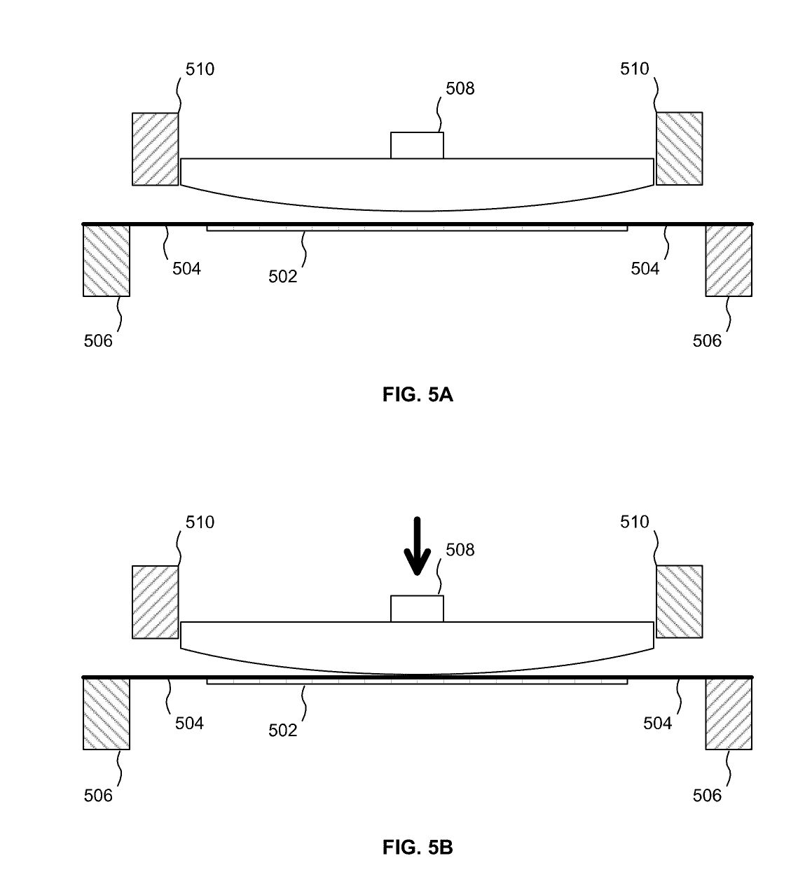

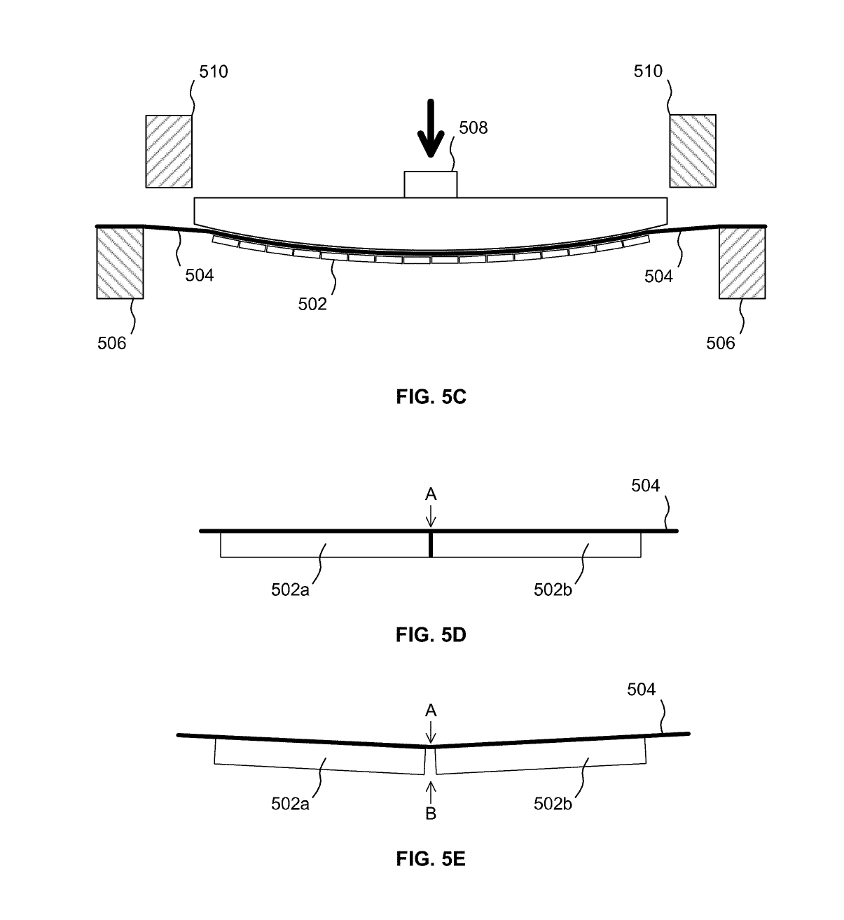

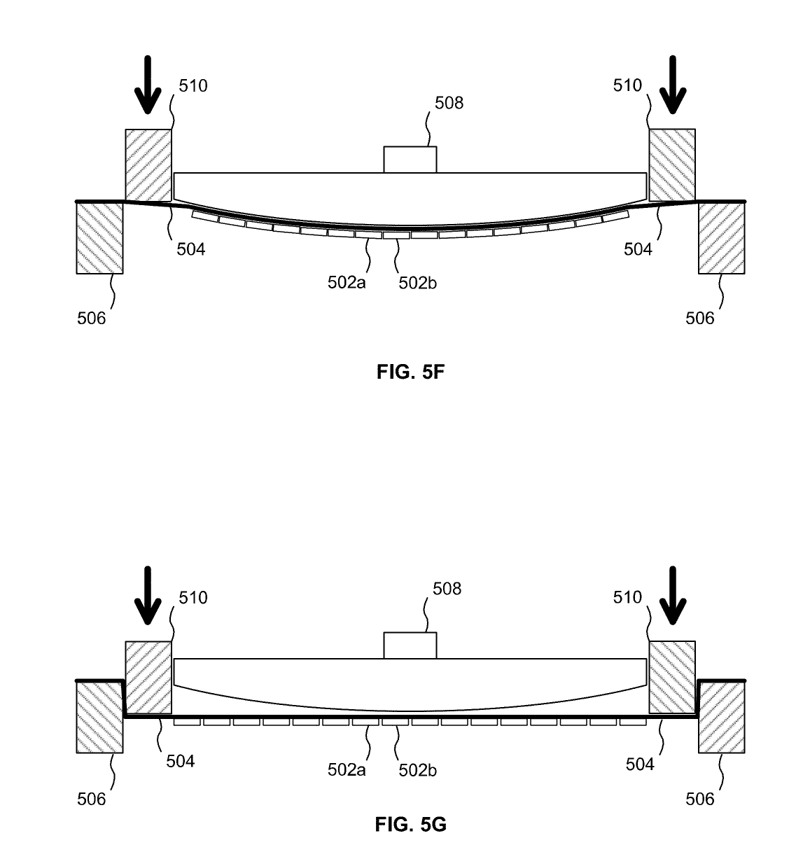

FIG. 5A is a side view of a stylized embodiment of a simultaneous break and expansion system, showing a pre-contact state for a curved surface (in this case applied from above, in contrast to application from below as in FIG. 4). A wafer substrate 502 is affixed to a dicing tape 504 in conventional fashion, and the dicing tape 504 is in turn affixed to a frame, such as the frame 406 from FIG. 4 (omitted from FIGS. 5A-5G for clarity). In the illustrated example, the dicing tape 504 is stretched across an outer expansion grip ring 506. The wafer substrate 502 is then scored by one of the means described above, such as the laser scribing and stealth dicing method described in co-pending U.S. patent application Ser. No. 15/432,838, referenced above. A 2-dimensionally curved surface 508 (e.g., an approximately spherical surface) is positioned so that it can be pressed against the scored wafer substrate 502 through the dicing tape 504; in this illustration, the curved surface 508 is in a pre-contact state. In this example, an inner expansion grip ring 510 is positioned so that it can be pressed against the dicing tape 504 at a later stage of operation. The illustrated embodiment thus uses an outer expansion grip ring 506 and an inner expansion grip ring 510 as tension maintenance devices, as described in greater detail below.

FIG. 5B is a side view of the stylized embodiment of the simultaneous break and expansion system of FIG. 5A, showing an initial contact state for the curved surface 508. In this illustration, the curved surface 508 has been pressed into initial contact with the dicing tape 504 holding the scored wafer substrate 502. As should be clear, the curved surface 508 may be moved to pressed engagement against the scored wafer substrate 502 (through the dicing tape 504), or the scored wafer substrate 502 may be moved to pressed engagement against the curved surface 508, or the two components may be mutually moved to pressed engagement against each other. The precise alignment required with breaker bar and cutter methods is eliminated because of the 2-dimensional radial symmetry of the curved surface 508.

In one embodiment, the curved surface 508 may be pressed against the dicing tape 504 (and hence the scored wafer substrate 502) so as to tension the dicing tape 504 about the same amount as would occur with application of standard ¼ inch expansion grip rings.

FIG. 5C is a side view of the stylized embodiment of the simultaneous break and expansion system of FIG. 5A, showing a full contact state for the curved surface. In this illustration, the curved surface 508 has been pressed into full contact with the dicing tape 504 holding the scored wafer substrate 502. The pressed 2-dimensionally curved surface 508 imposes 2-dimensional bending and separating actions on the joined dies of the scored wafer substrate 502, causing singulation on all die sides by breaking.

FIG. 5D is an enlarged view of two adjacent and joined dies 502a, 502b of the pre-expansion scored wafer substrate 502 of FIG. 5B. Application of pressure to the “top” side (as viewed in FIG. 5D) of the dicing tape 504 will cause a bending action to the scored wafer substrate 502 along the cutting street (marked “A”) between the joined dies 502a, 502b.

FIG. 5E is an enlarged view of two adjacent separated dies 502a, 502b of the post-separation scored wafer substrate 502 of FIG. 5C. Sufficient pressure has been applied to the dicing tape 504 and affixed scored wafer substrate 502 by the 2-dimensionally curved surface 508 to cause the formerly joined dies 502a, 502b to break apart (along all edges, not just along the cutting street marked “A”); the break is indicated at “B” on the “bottom” side (as viewed in FIG. 5E). In addition, stretching of the dicing tape 504 by the curved surface 508 has caused the singulated dies 502a, 502b to be laterally separated.

FIG. 5F is a side view of the stylized embodiment of the simultaneous break and expansion system of FIG. 5C, showing commencement of post-separation tensioning. As in FIG. 5C, the curved surface 508 is in a full contact state with the dicing tape 504, and the individual dies (e.g., 502a, 502b) of the scored wafer substrate 502 have been broken apart and are held in a spaced-apart relationship by the radial tension imparted by the curved surface 508. At this point, the inner expansion grip ring 510 is pressed against the dicing tape 504 to commence post-separation tensioning of the dicing tape 504.

FIG. 5G is a side view of the stylized embodiment of the simultaneous break and expansion system of FIG. 5F, showing completion of post-separation tensioning. At this point, the inner expansion grip ring 510 is at least partially nested within the outer expansion grip ring 506. As noted above, the outer and inner expansion grip rings 506, 510 work on the same principle as embroidery rings. Accordingly, as the inner expansion grip ring 510 is pressed against the dicing tape 504 in a nested configuration with the outer expansion grip ring 506, the pair of expansion grip rings 506, 510 will further stretch the dicing tape 504 and maintain the stretched state of the dicing tape 504 while or after the tension imposed by the curved surface 508 is removed. At this point in the process, the curved surface 508 can be separated from contact with the dicing tape 504 and scored wafer substrate 502, such as by retracting the curved surface 508 or retracting the frame (not shown) holding the dicing tape 504 and now-separated individual IC dies (e.g., 502a, 502b).

Pressing may be accomplished using a conventional manual press or automated press configured to hold a conventional frame 406, and adapted to hold the 2-dimensionally curved-surface 508 in a position to be pressed against a scored wafer substrate 502 affixed to a dicing tape 504 held by the frame 406. More generally, the invention encompasses a mechanism configured to hold the outer expansion grip ring 506 and affixed dicing tape 504 with the affixed scored wafer substrate 502; press the 2-dimensionally curved-surface 508 against the dicing tape 504 and affixed scored wafer substrate 502 to impose a bending force on the scored wafer substrate 502 sufficient to break and separate at least some of the joined IC dies apart from the scored wafer substrate 502 and stretch the dicing tape 504 so as to space apart the separated IC dies; and press an inner expansion grip ring 510 against the dicing tape 504 and into at least partial nested engagement with the outer expansion grip ring 506 sufficient to maintain the stretched dicing tape 504 in tension while or after the bending force imposed by the 2-dimensionally curved surface 508 is removed.

### Variations and Application Notes

While outer and inner expansion grip rings 506, 510 are a convenient way of maintaining post-separation tension on the dicing tape 504, other tension maintenance devices may be used to accomplish the same function. Note also that the nested outer and inner expansion grip rings 506, 510 may be separable from a handling frame so as to facilitate further IC fabrication processes, such as die picking.

The amount of “nesting” between the outer and inner expansion grip rings 506, 510 necessary to maintain a desired tension on the dicing tape 504 may vary depending on the “stretchiness” of the dicing tape 504, but in general, the inner expansion grip ring 510 will fully nest within the outer expansion grip ring 506. Further, the timing of application of the curved surface 508 to the dicing tape 504 and scored wafer substrate 502 versus application of the inner expansion grip ring 510 to the outer expansion grip ring 506 need not be purely sequential, as depicted in FIGS. 5A-5G. For example, the inner expansion grip ring 510 may be pressed against the dicing tape 504 to a desired degree while the curved surface 508 is in the process of being pressed against the dicing tape 504 and scored wafer substrate 502, so as to achieve a desired level of tension in the dicing tape 504 throughout the process, and/or to add radial tension to the scored wafer substrate 502 to assist breaking and separation.

In alternative embodiments, the curved surface 508 may be pressed directly against a scored wafer substrate 50. For example, referring to FIG. 5A, a stealth-diced scored wafer substrate 502 may be mounted upside-down on the dicing tape 504 (i.e., IC circuit side to tape) and the dicing tape 504 itself flipped over, such that the curved surface 508 would directly contact the scored wafer substrate 502.

Referring to FIG. 4, in one exemplary embodiment, the surface of the curved surface 410 that contacts the scored wafer substrate 402 was an approximately spherical surface having a radius R of approximately 78 inches for use in conjunction with an approximately 12 inch (˜300 mm) diameter wafer substrate. Other radii may be used for wafer substrates of the same or other sizes. In the exemplary embodiment, the lateral diameter D (i.e., perpendicular to the center line 412) of the curved surface 410 was sized to be only slightly larger than the diameter of the scored wafer substrate 402 so as to fit within the inner diameter of a wafer frame for a standard size wafer (e.g., 300 mm). However, in other embodiments, the lateral diameter D of the curved surface 410 may be sized to be substantially larger than the diameter of the scored wafer substrate 402.

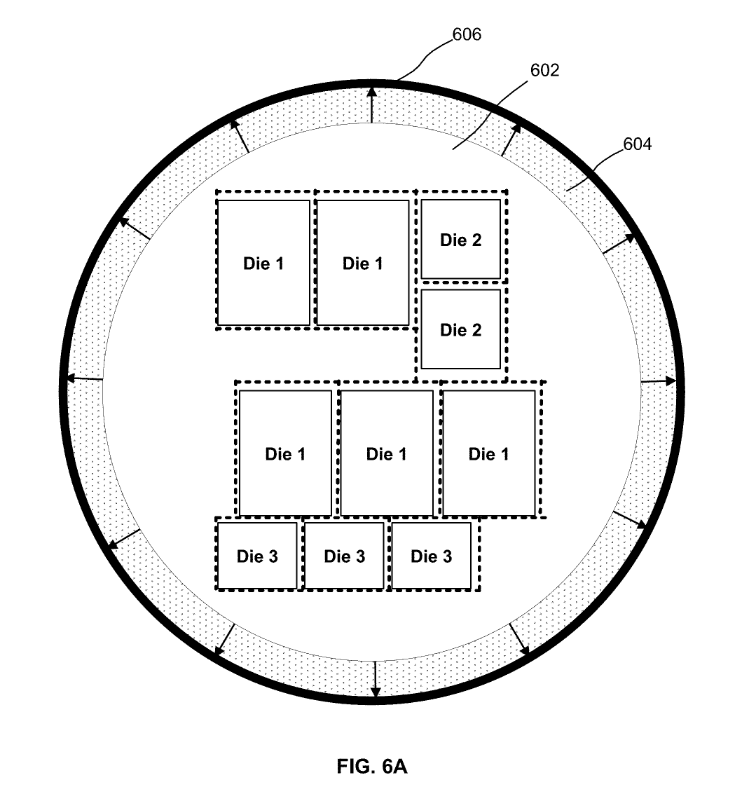

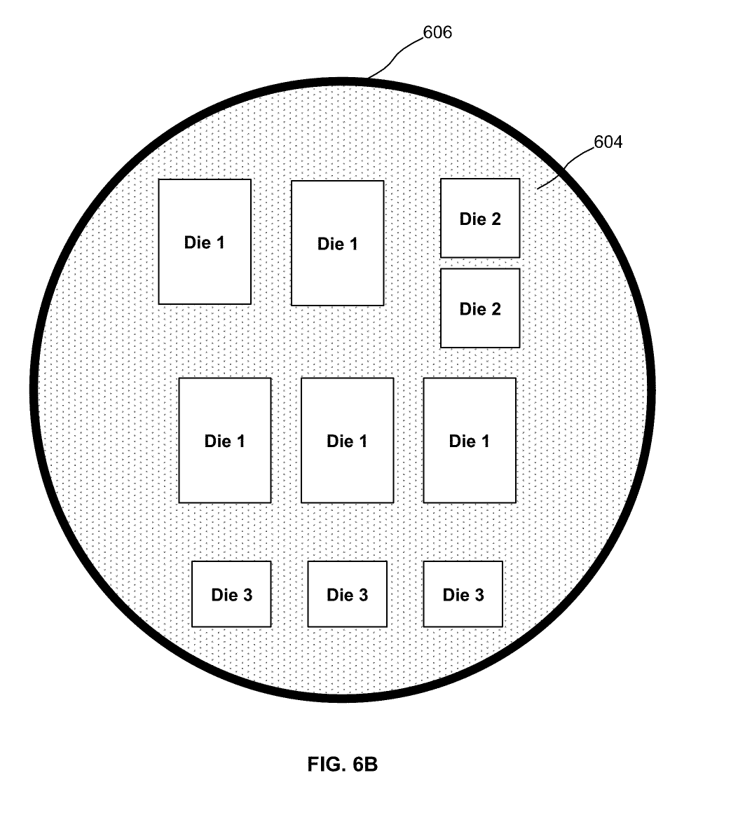

Embodiments of the invention may be applied to both uniform grid patterns IC die layouts and non-uniform grid pattern IC die layouts, such as multi-project wafers or multi-product wafers (MPWs). For example, FIG. 6A is a top plan view of a scored MPW substrate 602 mounted on a dicing tape 604 affixed to a frame (not shown) and stretched across or affixed to an outer expansion grip ring 606. The illustrated scored MPW substrate 602 has three different sized IC dies (Die 1, Die 2, Die 3) arranged in a non-uniform grid pattern layout. Dotted lines between the dies indicate cutting lanes in which scoring has occurred (e.g., by laser ablating, stealth dicing, etc.). As described above, pressing a curved surface against the dicing tape 604, and hence against the scored MPW substrate 602, will singulate (break) and separate the various dies, while post-separation tensioning of the dicing tape 604 with an inner expansion grip ring (not shown) will maintain the separation of the various dies. FIG. 6B is a top plan view of the post-separation state for FIG. 6A, showing the separation of the dies maintained by inner and outer expansion grip rings (for clarity, omitted are the non-die peripheral areas of the scored wafer substrate 602, shown in white in FIG. 6A).

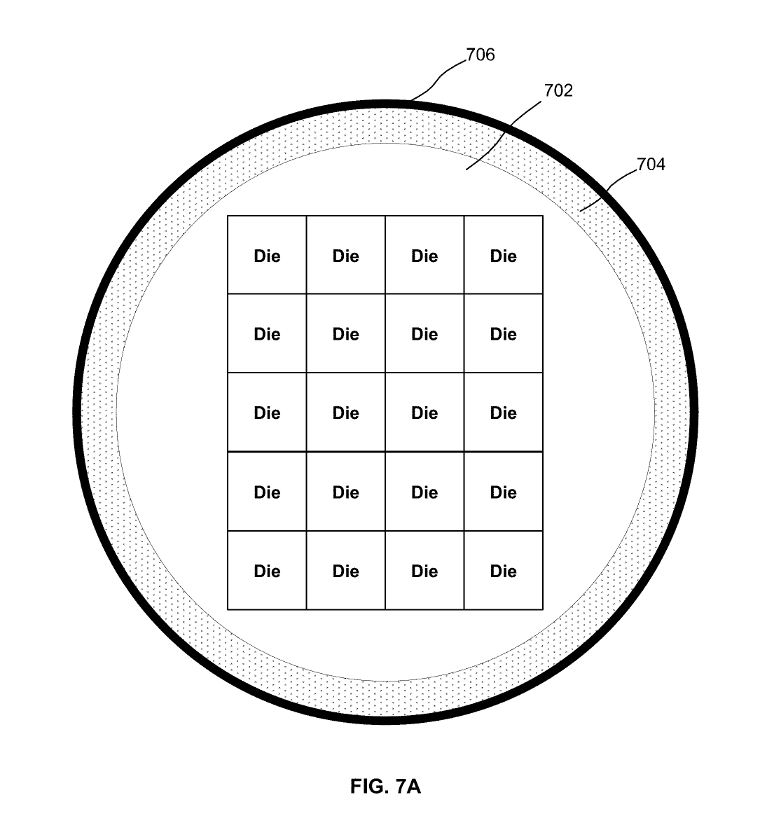

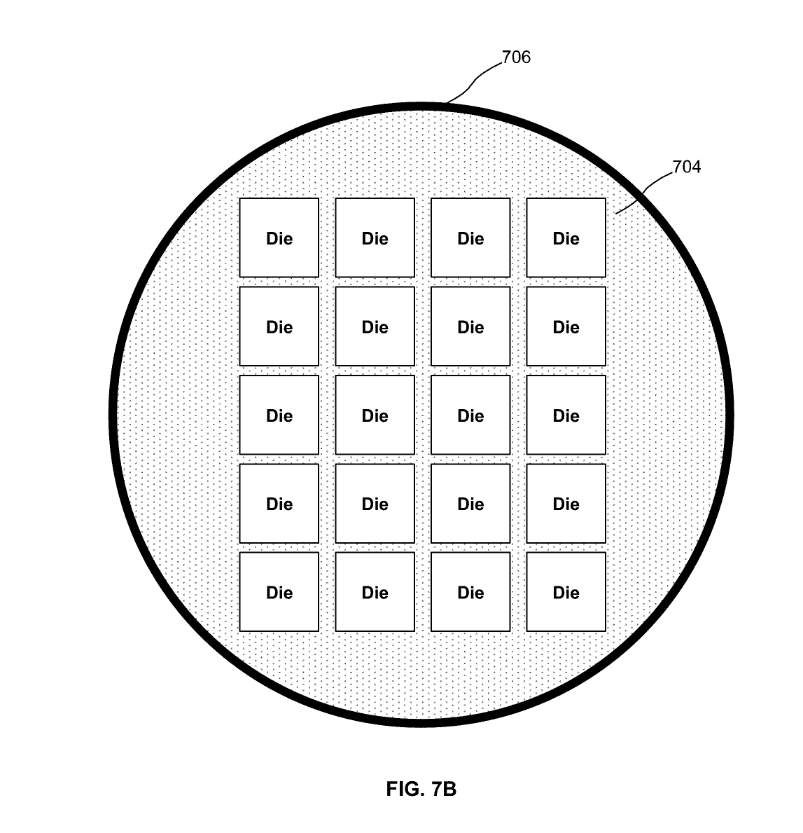

As another example, FIG. 7A is a top plan view of a scored wafer substrate 702 mounted on a dicing tape 704 affixed to a frame (not shown) and stretched across or affixed to an outer expansion grip ring 706. The illustrated scored wafer substrate 702 has same-sized IC dies arranged in a uniform grid pattern layout (cutting lanes are omitted for clarity). As described above, pressing a curved surface against the dicing tape 704, and hence against the scored wafer substrate 702, will singulate (break) and separate the various dies, while post-separation tensioning of the dicing tape 704 with an inner expansion grip ring (not shown) will maintain the separation of the various dies. FIG. 7B is a top plan view of the post-separation state for FIG. 7A, showing the separation of the dies maintained by the inner and outer expansion grip rings (for clarity, omitted are the non-die peripheral areas of the scored wafer substrate 702, shown in white in FIG. 7A).

In common automated wafer substrate processing systems, a wafer substrate undergoes a backgrind process in which a backgrind tape is adhered to the front side of the wafer substrate which has been patterned with IC dies. The backside of the wafer substrate is ground down by a grinder apparatus to achieve a desired thickness for the wafer substrate; optionally, the backside of the wafer substrate may be polished after grinding. An automated tape mounting system places the backside of the unscored thinned wafer substrate onto dicing tape affixed to a frame, and then the grinding tape is removed from the front side of the wafer substrate; optionally, a protective coating may be applied to the front side of the wafer substrate. The framed and dicing taped unscored wafer substrate is then scored and singulated as described above. Additional post-singulation steps may be applied, such as dicing tape adhesion release and die picking. As should be clear to one of ordinary skill in the art, additional steps may be performed in the process as desired, and some of the steps may be performed in a different order. For example, while it is most common to attach an unscored wafer substrate to a dicing tape affixed to a frame and then scoring the wafer substrate before singulating, the inventive concepts would apply as well to embodiments in which a scored wafer substrate is attached to a dicing tape affixed to a frame and then singulated. Additional details regarding various aspects of processing wafer substrates may be found in co-pending U.S. patent application Ser. No. 15/432,838, referenced above.

It should be recognized that the simultaneous break and expansion system described above may not produce a 100% yield for some IC dies sizes and geometries and some IC layouts on wafer substrates. However, it is believed that a high yield can generally be expected using embodiments of the present invention, including with very small dies (e.g., less than about 1.0 mm on the shortest edge).

Methods

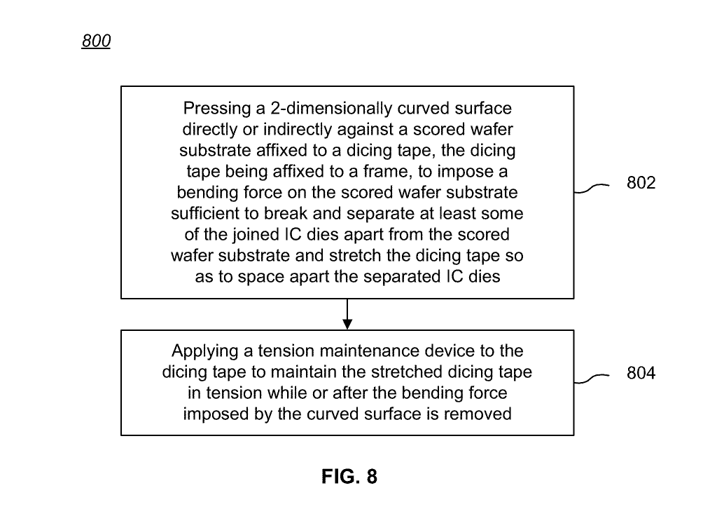

Another aspect of the invention includes methods for singulating joined integrated circuit (IC) dies from a scored wafer substrate. For example, FIG. 8 is a process flow diagram 800 showing a first method for singulating and separating joined IC dies from a wafer substrate, including: pressing a 2-dimensionally curved surface directly or indirectly against a scored wafer substrate affixed to a dicing tape, the dicing tape being affixed to a frame, to impose a bending force on the scored wafer substrate sufficient to break and separate at least some of the joined IC dies apart from the scored wafer substrate and stretch the dicing tape so as to space apart the separated IC dies (STEP 802); and applying a tension maintenance device to the dicing tape to maintain the stretched dicing tape in tension while or after the bending force imposed by the curved surface is removed (STEP 804).

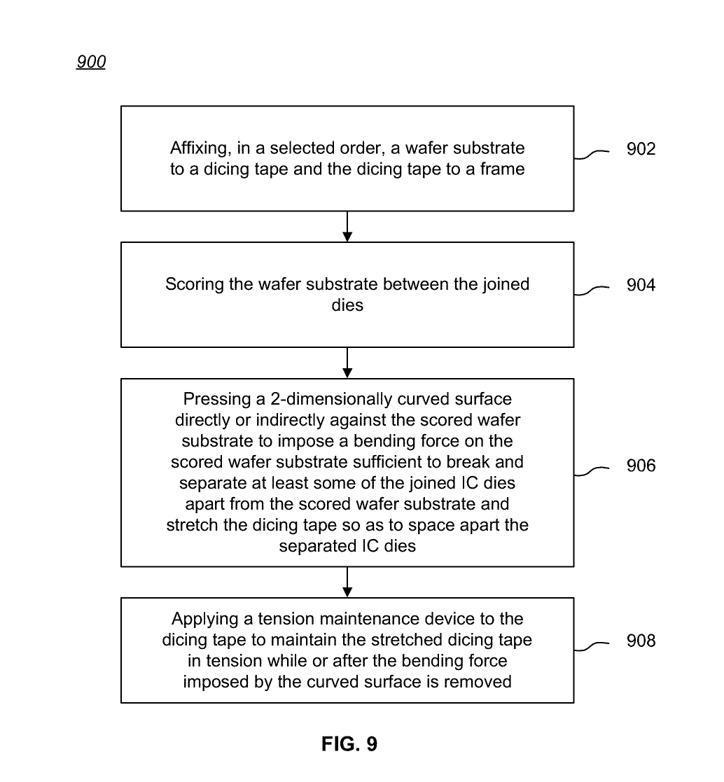

As another example, FIG. 9 is a process flow diagram 900 showing a second method for singulating and separating joined IC dies from a wafer substrate, including: affixing, in a selected order, the wafer substrate to a dicing tape and the dicing tape to a frame (STEP 902); scoring the wafer substrate between the joined dies (STEP 902); pressing a 2-dimensionally curved surface directly or indirectly against the scored wafer substrate to impose a bending force on the scored wafer substrate sufficient to break and separate at least some of the joined IC dies apart from the scored wafer substrate and stretch the dicing tape so as to space apart the separated IC dies (STEP 906); and applying a tension maintenance device to the dicing tape to maintain the stretched dicing tape in tension while or after the bending force imposed by the curved surface is removed (STEP 908).

Other aspects of the above methods include one or more of the following: the 2-dimensionally curved surface being moved to pressed engagement against the scored wafer substrate; the scored wafer substrate being moved to pressed engagement against the 2-dimensionally curved surface; the 2-dimensionally curved surface and the scored wafer substrate being mutually moved to pressed engagement against each other; the 2-dimensionally curved surface being pressed against the scored wafer substrate through the dicing tape; the 2-dimensionally curved surface being pressed directly against the scored wafer substrate; the 2-dimensionally curved surface having a lateral diameter sized to be only slightly larger than the diameter of the scored wafer substrate; the 2-dimensionally curved surface having a lateral diameter sized to be substantially larger than the diameter of the scored wafer substrate; the 2-dimensionally curved surface being an approximately spherical surface; the scored wafer substrate having an approximately 12 inch diameter and the approximately spherical surface having a radius R of approximately 78 inches; applying the set of expansion grip rings includes pressing an inner expansion grip ring into an outer expansion grip ring in a nested configuration; the scored wafer substrate being patterned with a uniform grid layout of IC dies; the scored wafer substrate being patterned with a non-uniform grid layout of IC dies; and/or the scored wafer substrate being a multi-project wafer or multi-product wafer.

Fabrication Technologies and Options

As should be readily apparent to one of ordinary skill in the art, various embodiments of the invention can be implemented to meet a wide variety of specifications. Unless otherwise noted above, selection of suitable component sizes and parameters is a matter of design choice, and various embodiments of the invention may be implemented in any suitable technology. As one example, the curved surface used in one experiment was formed by 3D printing to a desired contact surface radius and lateral diameter.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, or parallel fashion. It is to be understood that the foregoing description is intended to illustrate and not to limit the scope of the invention, which is defined by the scope of the following claims, and that other embodiments are within the scope of the claims. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A method for singulating and separating joined integrated circuit (IC) dies from a wafer substrate, including:
(a) pressing a 2-dimensionally curved surface directly or indirectly against a scored wafer substrate affixed to a dicing tape, the dicing tape being affixed to a frame, to impose a bending force on the scored wafer substrate sufficient to break and separate at least some of the joined IC dies apart from the scored wafer substrate and stretch the dicing tape so as to space apart the separated IC dies; and
(b) applying a tension maintenance device to the dicing tape to maintain the stretched dicing tape in tension while or after the bending force imposed by the 2-dimensionally curved surface is removed.

2. The method of claim 1, wherein the 2-dimensionally curved surface is moved to pressed engagement against the scored wafer substrate.

3. The method of claim 1, wherein the scored wafer substrate is moved to pressed engagement against the 2-dimensionally curved surface.

4. The method of claim 1, wherein the 2-dimensionally curved surface and the scored wafer substrate are mutually moved to pressed engagement against each other.

5. The method of claim 1, wherein the 2-dimensionally curved surface is pressed against the scored wafer substrate through the dicing tape.

6. The method of claim 1, wherein the 2-dimensionally curved surface is pressed directly against the scored wafer substrate.

7. The method of claim 1, wherein the 2-dimensionally curved surface has a lateral diameter sized to be only slightly larger than the diameter of the scored wafer substrate.

8. The method of claim 1, wherein the 2-dimensionally curved surface has a lateral diameter sized to be substantially larger than the diameter of the scored wafer substrate.

9. (canceled)

10. (canceled)

11. The method of claim 1, wherein applying the tension maintenance device includes pressing an inner expansion grip ring into an outer expansion grip ring in a nested configuration.

12. (canceled)

13. The method of claim 1, wherein the scored wafer substrate is patterned with a non-uniform grid layout of IC dies.

14. (canceled)

15. A method for singulating and separating joined integrated circuit (IC) dies from a wafer substrate, including:
(a) affixing, in a selected order, the wafer substrate to a dicing tape and the dicing tape to a frame;
(b) scoring the wafer substrate between the joined dies;
(c) pressing a 2-dimensionally curved surface directly or indirectly against the scored wafer substrate to impose a bending force on the scored wafer substrate sufficient to break and separate at least some of the joined IC dies apart from the scored wafer substrate and stretch the dicing tape so as to space apart the separated IC dies; and
(d) applying a tension maintenance device to the dicing tape to maintain the stretched dicing tape in tension while or after the bending force imposed by the 2-dimensionally curved surface is removed.

16. The method of claim 15, wherein the 2-dimensionally curved surface is moved to pressed engagement against the scored wafer substrate.

17. The method of claim 15, wherein the scored wafer substrate is moved to pressed engagement against the 2-dimensionally curved surface.

18. The method of claim 15, wherein the 2-dimensionally curved surface and the scored wafer substrate are mutually moved to pressed engagement against each other.

19. The method of claim 15, wherein the 2-dimensionally curved surface is pressed against the scored wafer substrate through the dicing tape.

20. The method of claim 15, wherein the 2-dimensionally curved surface is pressed directly against the scored wafer substrate.

21. The method of claim 15, wherein the 2-dimensionally curved surface has a lateral diameter sized to be only slightly larger than the diameter of the scored wafer substrate.

22. The method of claim 15, wherein the 2-dimensionally curved surface has a lateral diameter sized to be substantially larger than the diameter of the scored wafer substrate.

23. (canceled)

24. (canceled)

25. The method of claim 15, wherein applying the tension maintenance device includes pressing an inner expansion grip ring into an outer expansion grip ring in a nested configuration.

26. (canceled)

27. The method of claim 15, wherein the scored wafer substrate is patterned with a non-uniform grid layout of IC dies.

28.-44. (canceled)
